(19) United States
(12) Patent Application Publication
(10) Pub. No.: US 2009/0230992 A1
(43) Pub. Date: Sep. 17, 2009

(54) DATA TRANSMISSION CIRCUIT CAPABLE OF REDUCING CURRENT CONSUMPTION

(76) Inventor: Sung Joo HA, Ichon-si (KR)

Correspondence Address: LADAS & PARRY LLP, 224 SOUTH MICHIGAN AVENUE, SUITE 1600, CHICAGO, IL, 60604, US

(21) Appl. No.: 12/344,704

(22) Filed: Dec. 29, 2008

(30) Foreign Application Priority Data
Mar. 11, 2008 (KR) 10-2008-0022588

(51) Int. Cl. H03K 19/0175; G11C 7/00

(52) U.S. Cl. 326/63; 365/191

(57) ABSTRACT

A data transmission circuit includes a first signal transmission unit and a second signal transmission unit. The first signal transmission unit includes a driving unit having a plurality of driving devices used for driving and outputting an output signal at different logic levels according to driving signals. A driving signal generating unit selectively activates the driving signals using the input signal and according to control signals. A control unit generates the control signals using the current output signal which is fed back to the control unit, and the control signals are generated according to an enable signal. In the data transmission circuit, the current output signal is latched so that the driving devices only need to be activated when the desired signal is not latched. Thus the data transmission circuit can reduce current consumption and increase transmission speed.

### CROSS-REFERENCES TO RELATED APPLICATION

The present application claims priority under 35 U.S.C. 119(a) to Korean patent application number 10-2008-0022588, filed on Mar. 11, 2008 in the Korean Patent Office, which is incorporated herein by reference in its entirety.

### BACKGROUND OF THE INVENTION

The present invention relates generally to a semiconductor integrated circuit, and more particularly, to a data transmission circuit.

A typical semiconductor memory device includes a plurality of memory banks each including a plurality of memory cells, with the total number of memory cells numbering in the hundreds of thousands. Hierarchical input and output transmission lines are used for efficient transmission of data to/from the hundreds of thousands of memory cells that make up the plurality of memory banks.

The data input and output transmission lines include segment input and output lines, local input and output lines, and global input and output lines. Among these data input and output transmission lines, the global input and output lines are typically configured to bi-directionally transmit signals.

In order to achieve bi-directional transmission of the signals, a bi-directional inverter is provided between the global input and output lines. The bi-directional inverter disperses the data to be loaded to the global input and output lines.

Although the bi-directional inverter is necessary to achieve bi-direction transmission in the global input and output lines, the bi-direction inverter causes unnecessary short current (e.g., a current occurring when transistors of a circuit are at least partially turned on in such a manner as to allow current to flow directly from a source to ground) resulting in an undesirable increase in current consumption.

### SUMMARY

A data transmission circuit of a semiconductor integrated circuit capable of preventing a short current in a bi-directional inverter and then reducing a current consumption is described herein. According to one aspect, a data transmission circuit includes a control unit configured to generate control signals according to an enable signal; a driving signal generating unit configured to receive the control signals and an input signal to generate a driving signals, wherein the respective driving signals are selectively activated according to the control signals and the input signal; and a driving unit configured to generate an output signal, wherein the level of the output signal depends upon the driving signals, wherein the output signal is fed back to the control unit.

According to another aspect, a data transmission circuit comprises a data input and output line having a first input and output terminal and a second input and output terminal; a first signal transmission unit including a plurality of driving devices for driving an output signal at different logic levels to selectively activate the plurality of driving devices according to a logic level of a current output signal and to transmit data input through the first input and output terminal to the second input and output terminal; and a second signal transmission unit including a plurality of driving devices for driving an output signal at different logic levels to selectively activate the plurality of driving devices in the second signal transmission unit according to a logic level of a current output signal and to transmit data input through the second input and output terminal to the first input and output terminal.

These and other features, aspects, and embodiments are described below in the section entitled “Detailed Description.”

### BRIEF DESCRIPTION OF THE DRAWINGS

The above and other aspects, features and advantages of the subject matter of the present disclosure will be more clearly understood from the following detailed description taken in conjunction with the accompanying drawings, in which:

FIG. 1 is a block diagram showing an example of a data transmission circuit according to an embodiment of the present invention;

FIG. 2 is a block diagram showing an an embodiment of the first signal transmission unit shown in FIG. 1; and

FIG. 3 is a detailed circuit diagram showing an embodiment of the first signal transmission unit shown in FIG. 2.

### DETAILED DESCRIPTION

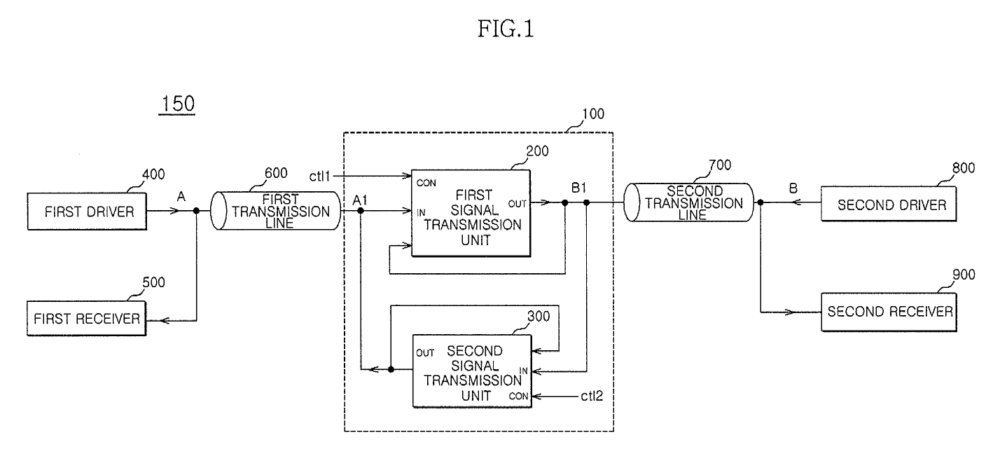

FIG. 1 is a block diagram showing a data transmission circuit according to an embodiment of the present invention.

A data transmission circuit 150 according to the embodiment of the present invention shown in FIG. 1 includes a signal transmission unit 100, a first driver 400, a first receiver 500, a first transmission line 600, a second transmission line 700, a second driver 800, and a second receiver 900.

The signal transmission unit 100 can include a first signal transmission unit 200 and a second signal transmission unit 300 as is shown in the embodiment of the present invention shown in FIG. 1.

The first signal transmission unit 200 is configured to receive a first enable signal ‘ctl1’ for enablement and a third signal ‘A1’, which is received from the first transmission line 600. The first signal transmission unit 200 outputs a fourth signal ‘B1’ to the second transmission line 700, and the output fourth signal ‘B1’ is fed back as an input of the first transmission signal. The fourth signal ‘B1’ is output according to the received first enable signal ‘ctl1’, third signal ‘A1’ and fourth signal ‘B1’ (described in more detail below). The first signal transmission unit 200 includes a plurality of driving devices for receiving the third signal ‘A1’ and for driving the fourth signal ‘B1’ so that the logic level of ‘B1’ is different from that of the third signal ‘A1’. In addition, the first signal transmission unit 200 is configured to selectively activate the driving devices included in the first signal transmission unit 200 according to the logic level of the fourth signal ‘B1’ when the first enable signal ‘ctl1’ is activated.

The second signal transmission unit 300 is configured to receive a second enable signal ‘clt2’ for enablement and the fourth signal ‘B1’, which is received from the second transmission line 700. The second signal transmission unit 300 outputs the third signal ‘A1’ to the first transmission line 600, and the third signal ‘A1’ is fed back as an input of the second signal transmission unit. The third signal ‘A1’ is output by the second signal transmission unit 300 according to the received second enable signal ‘clt2’, fourth signal ‘B1’ and third signal ‘A1’. The second signal transmission unit 300 includes a plurality of driving devices for receiving the fourth signal ‘B1’ and for driving the third signal ‘A1’ so that the logic level of the third signal ‘A1’ is different from that of the fourth signal ‘B1’. Similar to the first signal transmission unit 200, the second signal transmission unit 300 is configured to selectively activate the driving devices of the second signal transmission unit 300 according to the logic level of the third signal ‘A1’ when the second enable signal ‘ctl2’ is activated.

The first driver 400 and the second driver 800 are configured to drive the input signals thereof and to generate a first control signal ‘A’ and a second control signal ‘B’, respectively.

The first receiver 500 and the second receiver 900 receive the first control signal ‘A’ and the second control signal ‘B’, respectively.

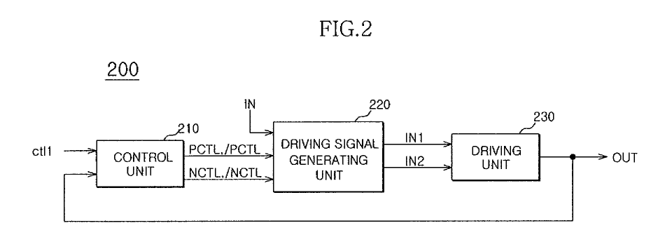

FIG. 2 is a block diagram showing an embodiment of the first signal transmission unit 200 shown in FIG. 1.

Referring to FIG. 2, the first signal transmission unit 200 can include a control unit 210, a driving signal generating unit 220, and a driving unit 230, as in the embodiment of the present invention shown in FIG. 2.

As shown in FIG. 2, the output signal ‘OUT’ of the driving unit 230 is fed back to the control unit 210, and the control unit 210 is configured to generate control signals ‘PCTL’, ‘/PCTL’, ‘NCTL’, and ‘/NCTL’ according to the fed back output signal ‘OUT’ and the first enable signal ‘ctl1’.

The driving signal generating unit 220 is configured to transmit or intercept an input signal ‘IN’ according to the received control signals ‘PCTL’, ‘/PCTL’, ‘NCTL’, and ‘/NCTL’ and to generate driving signals ‘IN1’ and ‘IN2’.

The driving unit 230 generates the output signal ‘OUT’ according to the received driving signals ‘IN1’ and ‘IN2’. At this time, the logic level of the output signal ‘OUT’ depends upon the logic levels of driving signals ‘IN1’ and ‘IN2’.

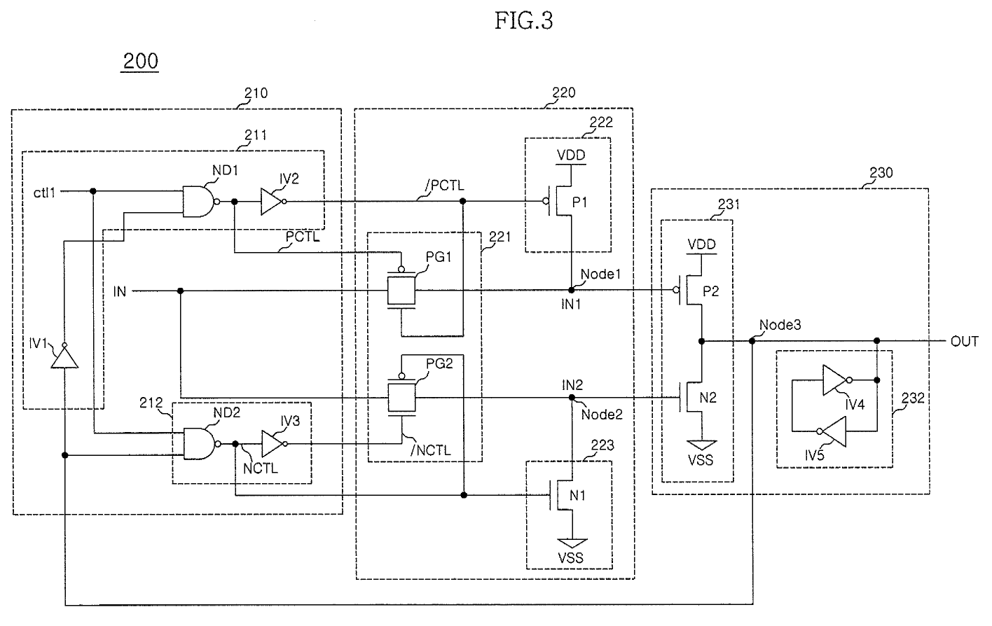

FIG. 3 is a detailed circuit diagram showing an embodiment of the first signal transmission unit shown in FIG. 2. Referring to FIG. 3, in detail, the outputs signal (at Node3) is fed back and input to the control unit 210, and the control unit 210 combines the output signal ‘OUT’ with the first enable signal ‘ctl1’ in order to output the first control signal ‘PCTL’. For example, in the embodiment shown in FIG. 3, when the enable signal ‘ctl1’ is enabled, the control unit 210 is configured to output the first control signal ‘PCTL’ such that the first control signal ‘PCTL’ has the same logic level as that of the output signal ‘OUT’ when the enable signal ‘ctl1’ is enabled, and to output the second control signal ‘NCTL’ such that the second control signal ‘NCTL’ has a logic level that is complementary to that of the output signal ‘OUT’. When the enable signal ‘ctl1’ is disabled, the control unit 210 is configured to disable the first control signal ‘PCTL’ and the second control signal ‘NCTL’.

The embodiment of the control unit 210 shown in FIG. 3 includes a first controller 211 and a second controller 212. The first controller 211 is configured to output the first control signal ‘PCTL’ such that the first control unit ‘PCTL’ has the same logic level as that of the output signal ‘OUT’ when the enable signal ‘ctl1’ is enabled.

The first controller 211 can include a first inverter ‘IV1’, a first NAND gate ‘ND1’, and a second inverter ‘IV2’. The first inverter ‘IV1’ inverts the output signal ‘OUT’. The first NAND gate ‘ND1’ receives the output of the first inverter ‘IV1’ and the enable signal ‘ctl1’ and performs a NAND logical operation on the output of the first inverter ‘IV1’ and the enable signal ‘ctl1’ to generate the first control signal ‘PCTL’. The second inverter ‘IV2’ receives the first control signal ‘PCTL’ and inverts the first control signal ‘PCTL’ to output the complementary signal ‘/PCTL’ of the first control signal ‘PCTL’.

The second controller 212 of the embodiment of the present invention shown in FIG. 3 is configured to output the second control signal ‘NCTL’ such that the second control signal ‘NCTL’ has a logic level that is complementary to that of the output signal ‘OUT’ when the enable signal ‘ctl1’ is enabled. The second controller 212 includes a second NAND gate ‘ND2’ and a third inverter ‘IV3’. The second NAND gate ‘ND2’ is configured to receive the output signal ‘OUT’ and the enable signal ‘ctl1’, and performs a NAND logical operation on the output signal ‘OUT’ and the enable signal ‘ctl1’ to output the second control signal ‘NCTL’. The third inverter ‘IV3’ receives the second control signal ‘NCTL’ and inverts the second control signal ‘NCTL’ to output the complementary signal ‘/NCTL’ of the second control signal ‘NCTL’.

The driving signal generating unit 220 is configured to directly transmit the logic level of the input signal ‘IN’ according to the first control signal ‘PCTL’ and the second control signal ‘NCTL’, or conversely to output the signal obtained by changing the logic level of the input signal ‘IN’ as the first driving signal ‘IN1’ or the second driving signal ‘IN2’.

The embodiment of the driving signal generating unit 220 shown in FIG. 3 includes a pass gate unit 221 and precharging units 222 and 223.

The pass gate unit 221 transmits the input signal ‘IN’ to output nodes ‘Node1’ and ‘Node2’ according to the first control signal ‘PCTL’ and the second control signal ‘NCTL’ and their respective complementary signals ‘/PCTL’ and ‘/NCTL’.

The precharging units 222 and 223 pre-charge the output nodes ‘Node1’ and ‘Node2’ of the pass gate unit 221 to a logic high level and a logic low level, respectively, according to the first control signal ‘PCTL’ and the second control signal ‘NCTL’.

The pass gate unit 221 of the embodiment of the present invention shown in FIG. 3 includes a first pass gate ‘PG1’ and a second pass gate ‘PG2’. The first pass gate ‘PG1’ transmits or intercepts (i.e., does not transmit) the input signal ‘IN’ according to the first control signal ‘PCTL’ and the complementary signal ‘/PCTL’ of the first control signal. The second pass gate ‘PG2’ transmits or intercepts (i.e., does not transmit) the input signal ‘IN’ according to the second control signal ‘NCTL’ and the complementary signal ‘/NCTL’ of the second control signal.

The precharging units 222 and 223 are hereinafter referred to as the first precharging unit 222 and the second precharging unit 223.

The first precharging unit 222 is configured to pre-charge the output node ‘Node1’ of the pass gate unit 221 to a logic high level according to the level of the complementary signal ‘/PCTL’ of the first control signal ‘PCTL’. The second precharging unit 223 is configured to pre-charge the output node ‘Node2’ of the pass gate unit 221 to a logic low level according to the level of the complementary signal ‘/NCTL’ of the second control signal ‘NCTL’.

The first precharging unit 222 can comprise a first PMOS transistor ‘P1’. The first PMOS transistor ‘P1’ receives the complementary signal ‘/PCTL’ of the first control signal ‘PCTL’ by the gate thereof and receives a supply voltage VDD by the source thereof. The node ‘Node1’ to which the first driving signal ‘IN1’ is output is connected to the drain of the first PMOS transistor ‘P1’.

The second precharging unit 223 can comprise a first NMOS transistor ‘N1’. The first NMOS transistor ‘N1’ receives the second control signal ‘NCTL’ by the gate thereof and receives a ground voltage VSS by the source thereof. The node ‘Node2’ to which the second driving signal ‘IN2’ is output is connected to the drain of the first NMOS transistor ‘N1’.

The embodiment of the driving unit 230 shown in FIG. 3 includes a driver 231 and a latch unit 232. The driver 231 includes a second PMOS transistor ‘P2’ driven according to the first driving signal ‘IN1’ and a second NMOS transistor ‘N2’ driven according to the second driving signal ‘IN2’. The output signal ‘OUT’ is output at the connection node between the second PMOS transistor ‘P2’ and the second NMOS transistor ‘N2’. The the second PMOS transistor ‘P2’ of the driver 231 is driven in response to the first driving signal ‘IN1’ to output the output signal ‘OUT’ at a logic high level when the first driving signal ‘IN1’ is enabled. The second NMOS transistor ‘N2’ of the driver 231 is driven in response to the second driving signal ‘IN2’ to output the output signal ‘OUT’ at a logic low level when the second driving signal ‘IN2’ is enabled. The second PMOS transistor ‘P2’ receives the first driving signal ‘IN1’ by the gate thereof and receives the supply voltage VDD by the source thereof. The drain of the second NMOS transistor ‘N2’ is connected to the drain of the second PMOS transistor ‘P2’ (the connection node between the two transistors). The second NMOS transistor ‘N2’ receives the second driving signal ‘IN2’ by the gate thereof and receives the ground voltage VSS by the source thereof. The drain of the second PMOS transistor ‘P2’ is connected to the drain of the second NMOS transistor ‘N2’.

The latch unit 232 is configured to maintain the logic level of the output signal ‘OUT’. The latch unit 232 of the embodiment shown in FIG. 3 includes a fourth inverter ‘IV4’ and a fifth inverter ‘IV5’. The fourth inverter ‘IV4’ receives the output of the fifth inverter ‘IV5’, inverts the output of the fifth inverter ‘IV5’ and outputs the inverted signal to the input terminal of the fifth inverter ‘IV5’. The fifth inverter ‘IV5’ receives the output signal ‘OUT’ and inverts the output signal ‘OUT’ to output the inverted signal to the input terminal of the fourth inverter ‘IV4’.

Hereinafter, the operation of the data transmission circuit according to an embodiment of the present invention will be described as follows.

When the enable signal ‘ctl1’ is at a logic low level, the control unit 210 outputs each of the first control signal ‘PCTL’ and the second control signal ‘NCTL’ at a logic high level (each of the NAND gates ND1 and ND2 received the logic low level and therefore output a logic high level). As such, the pass gate unit 221 of the driving signal generating unit 220 intercepts (i.e., does not pass) the transmission of the input signal ‘IN’ to the first node ‘Node1’ and the second node ‘node2’. In addition, the first precharging unit 222 in the driving signal generating unit 220 pre-charges the voltage level of the first node ‘Node1’ to a logic high level (the PMOS transistor is turned on by the logic low level received from the inverter IV2, since the inverter IV2 inverts the logic high level output by the NAND gate ND1) and the second precharging unit 223 in the driving signal generating unit 220 pre-charges the voltage level of the second node ‘Node2’ to a logic low level (the NMOS transistor N1 is turned on by the logic high level received from the NAND gate ND2).

Accordingly, when the control signal ctl1 is at a logic low level, the driver 231 of the driving unit 230 is not driven (the PMOS transistor P2 receives a logic high level and the NMOS transistor receives the logic low level, and therefore each is off), and therefore the driving unit maintains the current output signal ‘OUT’ latched by the latch unit 232.

On the other hand, when the enable signal ‘ctl1’ is at a logic high level, the second NMOS transistor N2 and the second PMOS transistor P2 of the driver 231 in the driving unit 230 are independently turned on or off according to the logic levels of the output signal ‘OUT’ fed back to the control unit 210 and the input signal ‘IN’ input to the pass gate unit 221 of the driving signal generation unit.

For example, when the output signal ‘OUT’ fed back to the control unit 210 is at a logic high level and the input signal ‘IN’ is in a logic low level, the first control signal ‘PCTL’ is at a logic high level since the NAND gate ‘ND1’ receives a logic high enable signal and a logic low inverted output signal ‘OUT’ (the output signal is inverted by ‘IV1’), and the second control signal ‘NCTL’ is at a logic low level since the NAND gate ‘ND2’ receives a logic high enable signal ctl1 and a logic low output signal ‘OUT’. Therefore, the pass gate ‘PG1’ of the pass gate unit 221 in the driving signal generating unit 220 does not transmit the input signal ‘IN’ to the first node ‘Node1’, however the pass gate ‘PG2’ does transmit the input signal ‘IN’ to the second node ‘Node2’. In addition, the first precharging unit 222 in the driving signal generating unit 220 receives a logic low signal from inverter ‘IV2’ and therefore pre-charges the voltage of the first node ‘Node1’ to a logic high level. Therefore, each of the second PMOS transistor ‘P2’ and the second NMOS transistor ‘N2’ in the driver 231 are turned off and are not driven since the first driving signal ‘IN1’ input to the PMOS transistor P2 is at a logic high level and the second driving signal ‘IN2’ input to the NMOS transistor N2 is at a logic low level. The output signal ‘OUT’ therefore maintains the logic level of the previous output signal ‘OUT’ which is latched in the latch unit 232.

When the output signal ‘OUT’ is at a logic high level and the input signal ‘IN’ is at a logic high level, the output of the control unit 210 is the same as described immediately above, and thus the first control signal ‘PCTL’ is at a logic high level and the second control signal ‘NCTL’ is at a logic low level. The first driving signal ‘IN1’ is at a logic high level since, although the pass gate ‘PG1’ of the pass gate unit 221 does not transmit the input signal ‘IN1’, the first precharging unit 222 is turned on by a logic low level received from the inverter ‘IV2’. In addition, since the pass gate unit 221 in the driving signal generating unit 220 transmits the input signal ‘IN’ to the second node ‘Node2’, the second driving signal ‘IN2’ is in a logic high level. Therefore, in the driver 231 of the driving unit 230, the second PMOS transistor ‘P2’ is turned off since it receives a logic high level and the second NMOS transistor ‘N2’ is turned on since it receives the logic high signal passed by the pass gate PG2. Therefore, the output signal ‘OUT’ is at a logic low level.

When the output signal ‘OUT’ is at a logic low level and the input signal ‘IN’ is at a logic low level, the first control signal ‘PCTL’ is at a logic low level since the NAND gate ND1 receives a logic high enable signal and a logic high inverted output signal ‘OUT’ and the second control signal ‘NCTL’ is at a logic high level since the NAND gate ND2 receives a logic high enable signal and a logic high output signal ‘OUT’. Therefore, the pass gate PG1 of the pass gate unit 221 in the driving signal generating unit 220 transmits the input signal ‘IN’ to the first node ‘Node1’ and the pass gate unit PG2 intercepts the transmission of the input signal ‘IN’ to the second node ‘Node2’. In addition, the first precharging unit 222 in the driving signal generating unit 220 is not driven since the PMOS transistor P1 receives a logic high complementary first control signal ‘/PCTL’ and the second precharging unit 223 pre-charges the second node ‘Node2’ to a logic low level since the NMOS transistor N1 receives a logic high second control signal ‘NCTL’. Therefore, the first driving signal ‘IN1’ is at a logic low level since the input signal ‘IN’ is passed by the pass gate ‘PG1’ and the second driving signal ‘IN2’ is at a logic low level since it is precharged by the second precharging unit 223. Therefore, in the driver 231 of the driving unit 230, the second PMOS transistor ‘P2’ is turned on by the logic low first driving signal ‘IN1’ and the second NMOS transistor ‘N2’ is turned off by the logic low second driving signal ‘IN2’. Therefore, the output signal ‘OUT’ is at a logic high level.

When the output signal ‘OUT’ is at a logic low level and the input signal ‘IN’ is at a logic high level the control unit 210 operates the same as that just described above. The first control signal ‘PCTL’ is at a logic low level and the second control signal ‘NCTL’ is at a logic high level. Therefore, the pass gate unit 221 in the driving signal generating unit 220 transmits the input signal ‘IN’ at a logic high level to the first node ‘Node1’. Therefore, the first driving signal ‘IN1’ is at a logic high level. The second precharging unit 223 precharges the second node ‘Node2’ to a logic low level. Therefore, the second PMOS transistor ‘P2’ and the second NMOS transistor ‘N2’ in the driver 231 are each turned off and are not driven. As such, the output signal ‘OUT’ maintains the logic low level of the previous output signal ‘OUT’ latched in the latch unit 232.

Thus, in the data transmission circuit according to an embodiment of the present invention, when the output signal ‘OUT’ is at a logic level that is the inverse of the input signal ‘IN’, the driver 231 is not driven and therefore the previous output signal ‘OUT’ latched in the latch unit 232 is directly output. In addition, in the data transmission circuit according to an embodiment of the present invention, when the output signal ‘OUT’ is at the same logic level as that of the input signal ‘IN’, the output signal ‘OUT’ is output at a logic level that is the inverse of the fed back output signal ‘OUT’. That is, when the input signal ‘IN’ is at a logic low level, only the second PMOS transistor ‘P2’ is driven, and when the input signal ‘IN’ is in a logic high level, only the second NMOS transistor ‘N2’ is driven. Therefore, unlike in the previous bi-directional inverter, it is possible to prevent current from being unnecessarily consumed. In addition, since the NMOS transistor and the PMOS transistor that configure the driving unit 231 are not simultaneously turned on as occurs in the conventional device, short current is reduced and the current that flows through the driver 231 is used for changing the logic level of the output signal ‘OUT’. Therefore, the transmission speed of data increases.

While certain embodiments have been described above, it will be understood that the embodiments described are by way of example only. Accordingly, the systems and methods described herein should not be limited based on the described embodiments. Rather, the systems and methods described herein should only be limited in light of the claims that follow when taken in conjunction with the above description and accompanying drawings.

What is claimed is:

1. A data transmission circuit comprising:
a control unit configured to generate control signals according to an enable signal;
a driving signal generating unit configured to receive the control signals and an input signal to generate a driving signals, wherein the respective driving signals are selectively activated according to the control signals and the input signal; and
a driving unit configured to generate an output signal, wherein the level of the output signal depends upon the driving signals,
wherein the output signal is fed back to the control unit.

2. The data transmission circuit of claim 1, wherein the driving unit comprises:
a first transmission device driven according to a first driving signal of the driving signals to output a first level; and
a second transmission device driven according to a second driving signal of the driving signals to output a second level.

3. The data transmission circuit of claim 1, wherein the driving signal generating unit is configured to directly transmit a logic level of the input signal or to output a signal obtained by changing the logic level of the input signal according to the control signals in order to output the driving signals.

4. The data transmission circuit of claim 3, wherein the driving signal generating unit comprises:
a pass gate unit for transmitting or intercepting the input signal according to the control signals; and
a precharging unit for precharging an output of the pass gate unit according to the control signals.

5. The data transmission circuit of claim 4, wherein the control signals comprise a first control signal and a second control signal each generated according to the enable signal, and
wherein the pass gate unit comprises:
a first pass gate configured to transmit or intercept the input signal according to the first control signal; and
a second pass gate configured to transmit or intercept the input signal according to the second control signal,
wherein when the first pass gate transmits the input signal, the transmitted input signal is a first driving signal of the driving signals, and when the second pass gate transmits the input signal, the transmitted input signal is a second driving signal of the driving signals.

6. The data transmission circuit of claim 5, wherein the precharging unit comprises:
a first precharging unit configured to precharge an output of the first pass gate to a logic high level according to a complementary signal of the first control signal; and
a second precharging unit configured to precharge an output of the second pass gate to a logic low level according to a complementary signal of the second control signal,
wherein the input signal transmitted by the first pass gate or the precharged output of the first pass gate is output as the first driving signal according to the first control signal, and
wherein the input signal transmitted by the second pass gate or the precharged output of the second pass gate is output as the second driving signal according to the second control signal.

7. The data transmission circuit of claim 1, wherein the control signals comprise a first control signal and a second control signal, and
wherein the control unit comprises:
a first controller configured to output the first control signal such that the first control signal has a logic level that is the same as that of the output signal when the enable signal is enabled; and
a second controller configured to output the second control signal such that the second control signal has a logic level that is complementary to that of the output signal when the enable signal is enabled.

8. The data transmission circuit of claim 7, wherein the first controller is configured to perform a NAND logical operation on the enable signal and an inverted signal obtained by inverting the output signal in order to output the first control signal.

9. The data transmission circuit of claim 7, wherein the second controller is configured to perform a NAND logical operation on the enable signal and the output signal in order to output the second control signal.

10. The data transmission circuit of claim 7, wherein the control unit is configured to disable each of the first control signal and the second control signal when the enable signal is disabled.

11. A data transmission circuit comprising a plurality of driving devices for driving an output signal at different logic levels, wherein the data transmission circuit is configured to selectively activate the plurality of driving devices according to a logic level of a current output signal that is fed back to obtain the output signal.

12. The data transmission circuit of claim 11, wherein the selectively activated driving devices are configured to drive the output signal such that the output signal is at a logic level that is different from that of the current output signal, and wherein the driving devices are inactive when the output signal is to maintain the same logic level as that of the current output signal.

13. The data transmission circuit of claim 12, further comprising a plurality of transmission devices for selectively transmitting an input signal to the plurality of driving devices according to the logic level of the output signal.

14. The data transmission circuit of claim 13, wherein the driving devices include a first driving device and a second driving device, and the transmission devices are configured such that:
when each of the current output signal and the input signal are a logic low level, the first driving device is activated to output a logic high level and the second driving device is deactivated such that the output signal is output at a logic high level, and
when each of the current output signal and the input signal are a logic high level, the second driving device is activated to output a logic low level and the first driving device is deactivated such that the output signal is output at a logic low level, and
when the current output signal and the input signal are at different logic levels, each of the first and second driving devices are deactivated so that the output signal is output to have a logic level that is the same as that of the current output signal.

15. A data transmission circuit comprising:
a data input and output line having a first input and output terminal and a second input and output terminal;
a first signal transmission unit comprising a plurality of driving devices for driving an output signal at different logic levels, wherein first signal transmission unit being configured to selectively activate the plurality of driving devices according to a logic level of a current output signal that is fed back from the first signal transmission unit and configured to transmit data input through the first input and output terminal to the second input and output terminal; and
a second signal transmission unit comprising a plurality of driving devices for driving an output signal at different logic levels, wherein the second signal transmission unit is configured to selectively activate the plurality of driving devices in the second signal transmission unit according to a logic level of a current output signal that is fed back from the second signal transmission unit and configured to transmit data input through the second input and output terminal to the first input and output terminal.

16. The data transmission circuit of claim 14, wherein the selectively activated driving devices of each of the first and second signal transmission units are configured to drive the output signal such that the output signal is at a logic level that is different from that of the logic level of the current output signal of the respective first and second transmission units, wherein the driving devices of each of the first and second signal transmission units are inactive when the output signal is to maintain the same logic level as that of the current output signal of the respective first and second transmission units.

17. The data transmission circuit of claim 15, wherein the first signal transmission unit comprises:
a driving unit comprising the plurality of driving devices for driving the output signal at different logic levels according to driving signals;
a driving signal generating unit configured to selectively activate the driving signals using the data input through the first input and output terminal according to control signals; and
a control unit for generating the control signals using the current output signal according to an enable signal.

18. The data transmission circuit of claim 16, wherein the driving signals include a first driving signal and a second driving signal, and the driving unit comprises;
a first transmission device driven according to the first driving signal to output a first logic level; and
a second transmission device driven according to the second driving signal.

19. The data transmission circuit of claim 16, wherein the driving signal generating unit is configured to directly transmit a logic level of the input signal or to output a signal obtained by changing the logic level of the input signal according to the control signals in order to output the driving signals as a first driving signal and a second driving signal.

20. The data transmission circuit of claim 16, wherein the control signals comprise a first control signal and a second control signal, and
wherein the control unit comprises:
a first controller configured to output the first control signal such that the second control signal has a logic level that is the same as that of the output signal when the enable signal is enabled; and
a second controller configured to output the second control signal such that the second control signal has a logic level that is complementary to that of the output signal when the enable signal is enabled.
